(19) United States
(12) Patent Application Publication
(10) Pub. No.: US 2012/0175607 A1
(43) Pub. Date: Jul. 12, 2012

(54) THIN FILM TRANSISTOR STRUCTURE AND MANUFACTURING METHOD THEREOF

(75) Inventors: FANG-AN SHU, Hsinchu City (TW); HENRY WANG, Hsinchu City (TW); CHIA-CHUN YEH, Hsinchu City (TW); TED-HONG SHINN, Hsinchu City (TW)

(73) Assignee: E Ink Holdings Inc., Hsinchu City (TW)

(21) Appl. No.: 13/337,411

(22) Filed: Dec. 27, 2011

(30) Foreign Application Priority Data
Jan. 7, 2011 (TW) 100100713

(51) Int. Cl. H01L 33/08; H01L 21/336

(52) U.S. Cl. 257/43; 438/158; 257/E33.053; 257/E21.412

(57) ABSTRACT

A thin film transistor (TFT) structure includes a substrate, a gate, a gate dielectric layer, a source, a drain and a transparent material layer. The gate is formed on the substrate; the gate dielectric layer is formed on the gate; the source and the drain are formed on the gate dielectric layer; and the transparent material layer has a channel area and an insulating area, and the channel area is disposed on a portion of the gate dielectric layer located between the source and the drain; and the insulating area is disposed on the channel area, the source and the drain.

### FIELD OF THE INVENTION

The present invention relates to a semiconductor structure and the method for fabricating the same, and more particularly to a thin film transistor (TFT) structure and the manufacturing method thereof.

### BACKGROUND OF THE INVENTION

FIG. 1A illustrates a top view of a thin film transistor structure 10 in accordance with prior art. FIG. 1B is a cross-sectional view of the thin film transistor structure 10 depicted along the dotted line C-C′ drawn in FIG. 1A. The thin film transistor structure 10 includes a thin film circuit area 12 and a pixel area 14, wherein the thin film circuit area 12 has a data line 121, a scan line 122, a Cs line 123 and a thin film transistor 100; and the pixel area 14 has a pixel electrode 112.

The formation of the thin film transistor structure 10 includes steps as follows: a scan line 122 and a Cs line 123 are firstly formed on a glass substrate 101, wherein a portion of the scan line 122 is used to serve as the metal gate electrode 102 of a thin film transistor 100 subsequently defined in the thin film transistor structure 10 (see FIG. 1B). Next a gate dielectric layer 104 and a semiconductor channel layer 110 are then formed on the metal gate electrode 102 in sequence. Subsequently, a metal layer disposed on the semiconductor channel layer 110 is patterned by using a lithography-etching process to form a data line 121 and a drain 105, while a source 103 composed of a portion of the data line 121 is defined on the semiconductor channel layer 110. A passive layer 109 and a protection layer 111 are then covered on the source 103 and the drain 105 to form the thin film transistor 100. Thereinafter, a transparent pixel electrode 112 made of transparent materials is formed on the gate dielectric layer 104, and then the transparent pixel electrode 112 is electrically connected to the drain 105.

In sum, the thin film transistor 10 fabricating process requires several photo masks, and a certain amount of contact via holes 106 formed between the transparent pixel electrode 112 and the drain 105. Thus it is difficult to simplify the manufacture process, such that problems of high processing cost as long as low yield may be triggered.

Besides, in the light of the fact that photo-leakage current usually occurs on the typical amorphous silicon based semiconductor channel layer 110, indium tin oxide (ITO) which has characteristics of high carrier mobility and visible light transparency has been used to substitute the amorphous silicon to form the semiconductor channel layer 110 of the thin film transistor 100 in order to improve the performance of the thin film transistor structure 10.

However, indium tin oxide (ITO) film is vulnerable and susceptible to moisture and oxygen, thus when the indium tin oxide (ITO) film is involved in a thin film transistor manufacturing process which includes steps such as coating, etching and photo-resist striping, the indium tin oxide (ITO) film may be damaged by the moisture and oxygen during the manufacturing process, and the yield of the thin film transistor structure 10 may thus be deteriorated.

Therefore, it is necessary to provide an improved thin film transistor structure and a method for fabricating the same to decrease the manufacturing cost and improve the yield of the thin film transistor structure.

### SUMMARY OF THE INVENTION

One aspect of the present invention is to provide a thin film transistor structure, comprising a substrate, a gate, a gate dielectric layer, a source, a drain and a transparent material layer. The gate is formed on the substrate; the gate dielectric layer is formed on the gate. The source and the drain are formed on the gate dielectric layer. The transparent material layer has a channel area and an insulating area, wherein the channel area is disposed on a portion of the gate dielectric layer located between the source and the drain; and the insulating area is disposed on the channel area, the source and the drain.

Another aspect of the present invention is to provide a method for fabricating a thin film transistor structure, wherein the method includes steps as follows: a substrate is firstly provided and a gate is then formed on the substrate. Next, a gate dielectric layer is formed on the gate. A source and a drain are then formed on the gate dielectric layer. A transparent material layer having a channel area and an insulating area is subsequently formed, wherein the channel area is disposed on a portion of the gate dielectric layer located between the source and the drain; and the insulating area covers on the channel area, the source, and the drain.

According to aforementioned embodiments, a thin film transistor structure and the manufacturing method thereof are provided. A continuous sputtering deposition is performed to form a transparent material layer, wherein the transparent material layer having a channel area and an insulating area overlays on the gate dielectric layer, the source and the drain without venting. During the continuous sputtering deposition, the concentration of oxygen implanted into the channel area and the insulating area can be adjusted by controlling the oxygen (O₂)/argon (Ar) flow rate of the sputtering deposition atmosphere. Therefore, the channel area and the insulating area can be formed in a single semiconductor layer by a single process; such that, the procedures for manufacturing the thin film transistor structure can be simplified, the manufacturing cost can be reduced; and yield of the thin film transistor structure can be improved.

Besides, since the present method can further provides the indium tin oxide (ITO) based source and drain structure, wherein the drain has an extending portion serves as a pixel electrode electrically connected to the pixel layer, thus the additional contact via holes definition process and the process for forming the conventional pixel electrode is not essential any more and even can be omitted, and the photo masks required by the aforementioned process also can be omitted. Accordingly the manufacturing procedures can be simplified; meanwhile the aperture ratio of an LCD which utilizes the present thin film transistor structure can be improved.

In order to make the aforementioned and other objects, features and advantages of the present invention comprehensible, preferred embodiment accompanied with figures are described in detail below.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1A illustrates a top view of a thin film transistor structure in accordance with prior art.

FIG. 1B is a cross-sectional view of the thin film transistor depicted along the dotted line C-C′ drawn in FIG. 1A.

FIG. 2 illustrates a top view of a thin film transistor structure in accordance with one embodiment of the present invention.

FIGS. 2A to 2E are cross-sectional views depicted along the dotted line S-S′ of FIG. 2 used to illustrate the process for fabricating the thin film transistor structure.

FIG. 3 illustrates a cross-sectional view of a thin film transistor structure in accordance with another embodiment of the present invention.

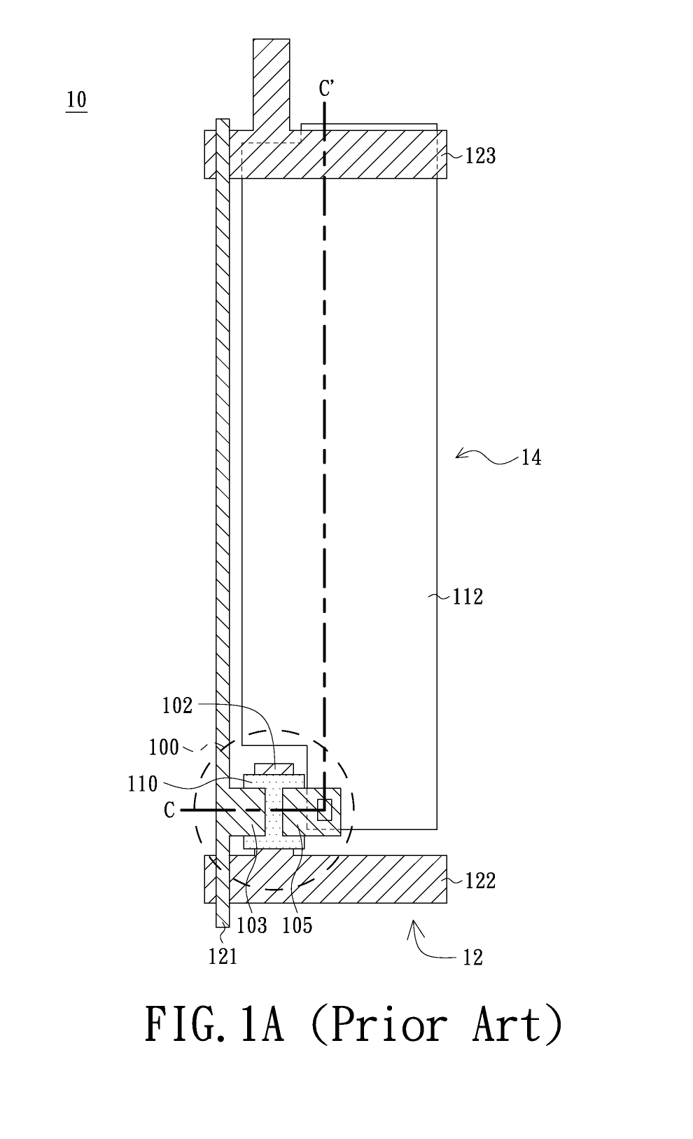

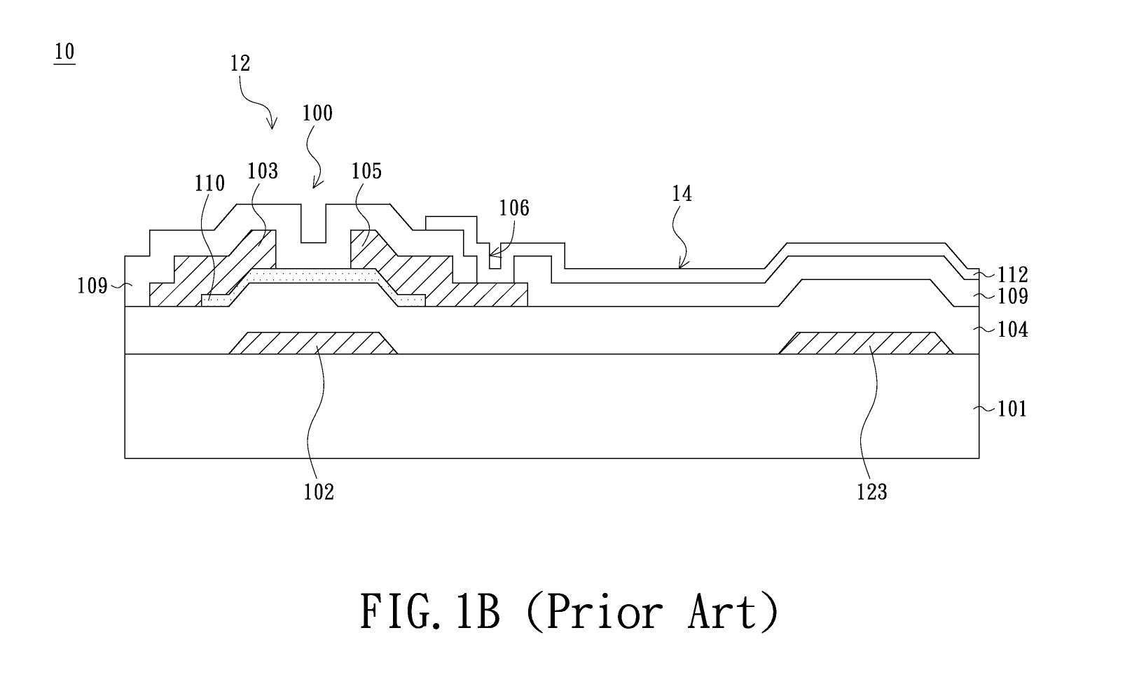

### DETAILED DESCRIPTION OF PREFERRED EMBODIMENTS

Detail descriptions of several embodiments eligible to exemplify the features of making and using the present invention are disclosed as follows. It must be appreciated that the following embodiments are just example, but not used to limit the scope of the present invention. Wherever possible, the same reference numbers are used in the drawings and the description to refer to the same or like parts.

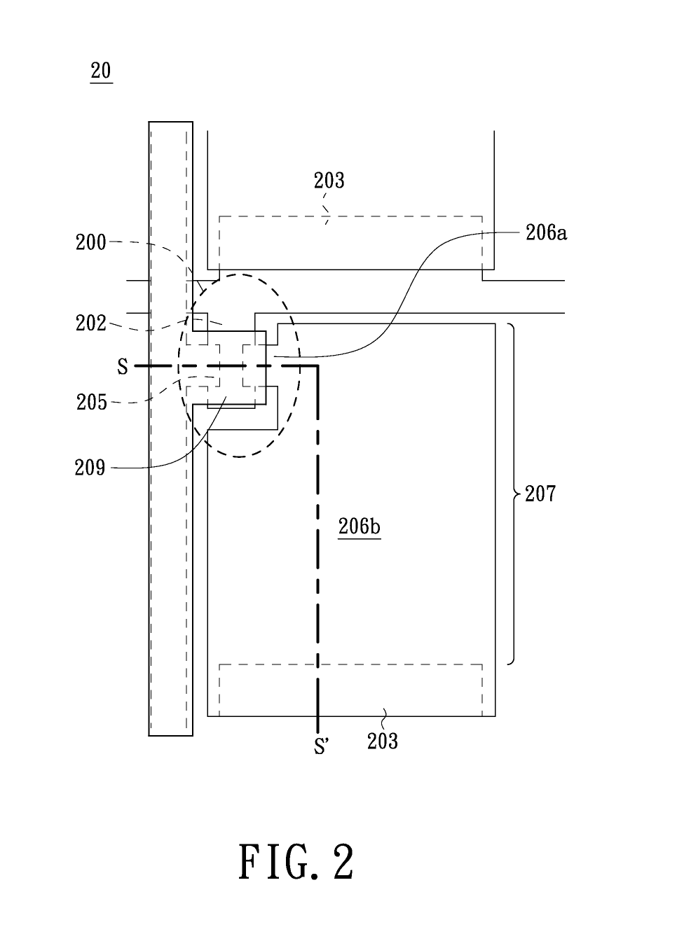

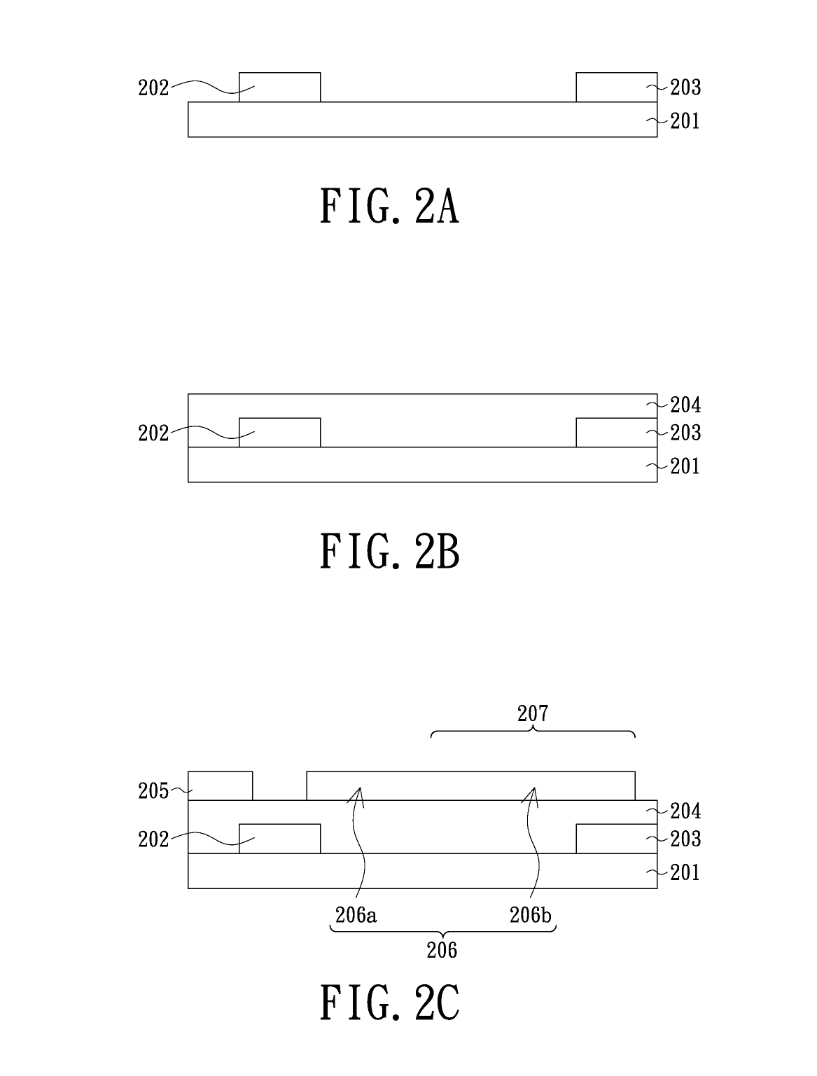

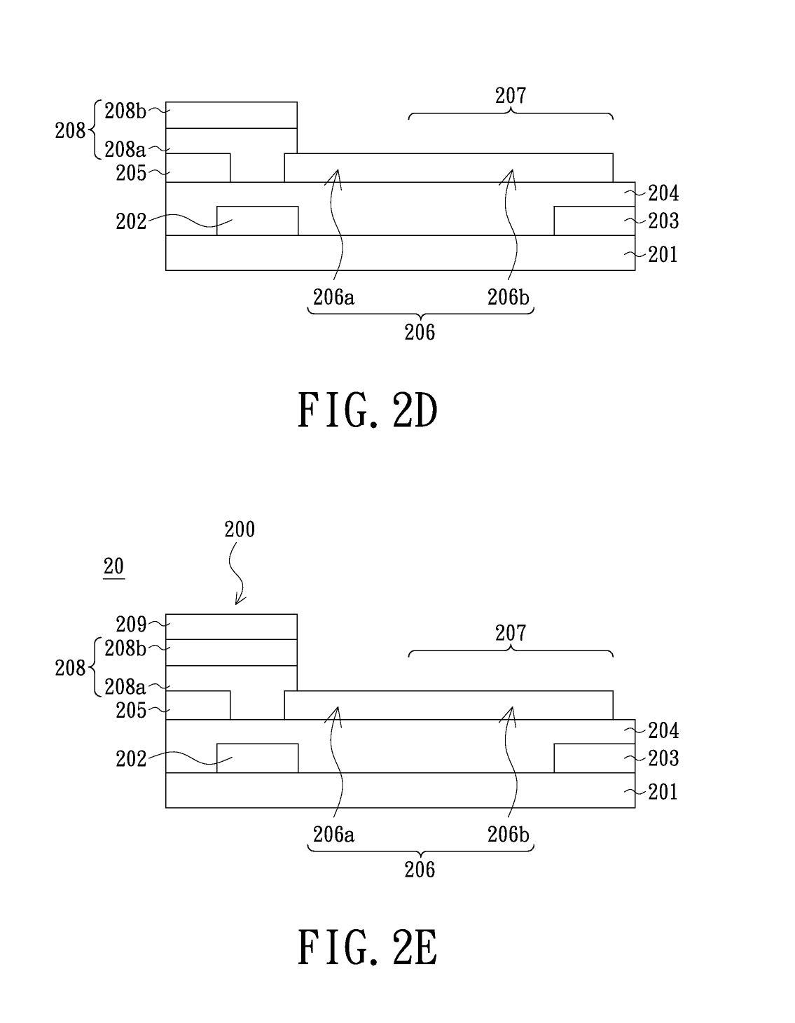

One of the objects of the present invention is to provide a thin film transistor structure and the fabricating method thereof. FIG. 2 illustrates a top view of a thin film transistor structure 20 in accordance with one embodiment of the present invention. FIGS. 2A to 2E are cross-sectional views depicted along the dotted line S-S′ of FIG. 2 used to illustrate the process for fabricating the thin film transistor structure 20. The method for fabricating the thin film transistor structure 20 includes steps as follows:

A substrate 201 is firstly provided and a gate 202 is then formed on the substrate 201. In some embodiments of the present invention, the substrate 201 is a glass substrate or a plastic substrate; and the gate 202 may consist of poly-silicon or metal materials. In the present embodiment, the formation of the gate 202 includes steps of patterning a metal layer deposited on the substrate 201. In addition, another metal layer 203 (shown in FIG. 2A) which can serve as a storage capacitor is formed on the substrate 201 simultaneous to the formation of the gate 202.

Next, a gate dielectric layer 204 (shown in FIG. 2B) is formed on the gate 202 and the metal layer 203. The material used to form the gate dielectric layer 204 preferably is selected from the group consisting of silicon nitride (SiNₓ), silicon oxide (SiOₓ), silicon oxy-nitride (SiNₓO_{y}), aluminum oxide (AlOₓ), hafnium oxide (HfOₓ) and the arbitrary combinations thereof. In the present embodiment, the gate dielectric layer 204 is a silicon oxide (SiOₓ) layer deposited on the gate 202.

A source 205 and a drain 206 are then formed on the gate dielectric layer 204 (shown in FIG. 2C). The material consisting of the source 205 and the drain 206 preferably is indium tin oxide (ITO), indium zinc oxide (IZO), indium gallium zinc oxide (IGZO) or the arbitrary compositions thereof. In the present embodiment, the formation of the source 205 and the drain 206 includes steps of depositing a transparent indium tin oxide (ITO) layer on the gate 202, and patterning the transparent ITO layer, in order to define the source 205 and drain 206 separated from each other and expose a portion of the gate dielectric layer 204 disposed on the gate 202 and located between the separated source 205 and drain 206.

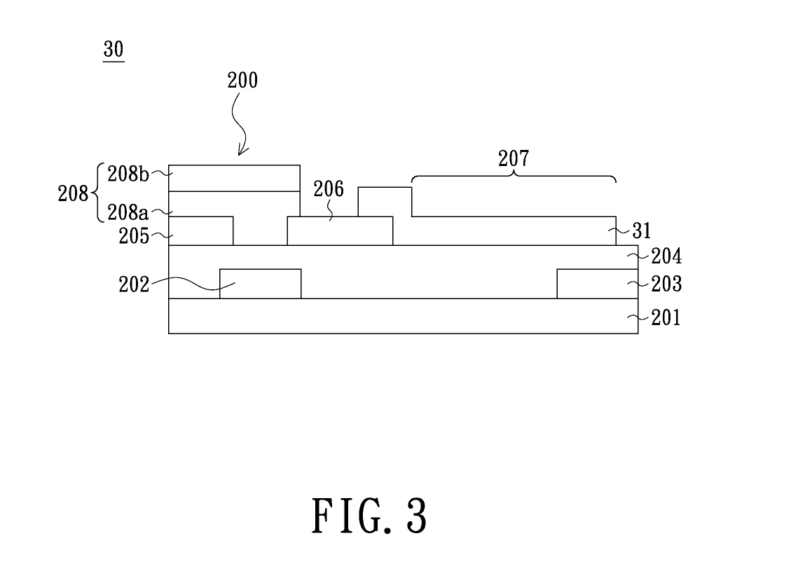

Besides, the thin film transistor structure 20 further includes a pixel electrode layer 206b formed on the gate dielectric layer 204 and electrically connected to the drain 206. In the present embodiment, the drain 206 and the pixel electrode layer 206b are formed by a same conductive layer. Specifically, the drain 206 has an extending portion 206a extending to contact with a pixel area 207 which allows light passing there through to form the pixel electrode layer 206b. The pixel electrode 206b can be used to control the operation of a liquid crystal display (LCD) which utilizes the thin film transistor structure 20 as an operation device. However in another embodiment of the present invention, the thin film transistor structure 30 may, otherwise, includes a separated pixel electrode layer 31 formed on the gate dielectric layer 204 and electrically connected to the drain 206 (shown in FIG. 3).

Subsequently, a deposition process is conducted to form a transparent material layer 208 blanket over the gate dielectric layer 204, the source 205 and the drain 206. A patterning processes including photo-resist coating, etching, and photo-resist striping steps is then conducted to define a channel area 208a and an insulating area 208b on the transparent material layer 208 (shown in FIG. 2D), wherein the channel area 208a is disposed on a portion of the gate dielectric layer 204 located between the source 205 and the drain 206; and the insulating area 208b covers on the source 205 and the drain 206.

In some embodiments of the present invention, the formation of the transparent material layer 208 includes performing a continuous sputtering process in order to deposit indium gallium zinc oxide (IGZO) material onto the gate dielectric layer 204, the source 205 and the drain 206 without venting. The concentration of oxygen implanted into the channel area 208a and the insulating area 208b can be adjusted by controlling the oxygen (O₂)/argon (Ar) flow rate of the sputtering deposition atmosphere.

In the present embodiment, the continuous sputtering deposition includes steps as follows: an atmosphere with a low O₂ concentration (substantially about 3%˜5%) is firstly provided to form a indium gallium zinc oxide (IGZO) film denominated as the channel area 208a on a portion of the gate dielectric layer 204 located between the source 205 and the drain 206; and while the sputtering deposition is continued, another atmosphere with a high O₂ concentration is subsequently provided without venting to form another indium gallium zinc oxide (IGZO) film denominated as the insulating area 208b on the source 205 and the drain 206. Because the indium gallium zinc oxide (IGZO) layer of the channel area 208a is implanted with less oxygen atoms than the indium gallium zinc oxide (IGZO) layer of the insulating area 208b; thus the channel area 208a may possess semiconductor properties and the insulating area 208b may, otherwise, possess insulating properties. In the present embodiment, the channel area 208a has a molecular proportion of indium (In), gallium (Ga), zinc (Zn) and Oxygen (O) substantially about 1:1:1:(3.5˜4.5), a thickness substantially ranges from 50 nm to 100 nm and a resistance substantially ranges from 1×10¹ ohm-cm to 1×10⁶ ohm-cm; and the insulating area 208b has a thickness substantially ranges from 50 nm to 500 nm and a resistance substantially greater than 1×10⁶ ohm-cm.

Since the channel area 208a and the insulating area 208b are formed by a single one film-forming process without venting, some processes traditionally use to form the thin film transistor structure 20 (including some complicate photo-resist coating, etching, and photo-resist striping steps essential required by the prior art) are no longer necessary. Accordingly, the process for manufacturing the thin film transistor structure 20 can be simplified and the processing cost can be reduced. Besides, by utilizing the present approach, the indium gallium zinc oxide (IGZO) layer used to compose the channel area 208b can be prevented from the moisture and oxygen damage caused by the photo-resist coating, etching, and photo-resist striping steps. Therefore, the drawbacks and problems encountered from the prior art can be obviated.

In some embodiments of the present invention, the thin film transistor structure 20 further includes a protection layer 209 formed on the insulating area 208b, the pixel electrode 206b and the exposed portion of the gate dielectric layer 204, wherein the protection layer 209 is composed of material selected from the group consisting of silicon nitride (SiNₓ), silicon oxide (SiOₓ), silicon oxy-nitride (SiNₓO_{y}), aluminum oxide (AlOₓ), resin and the arbitrary combinations thereof (shown in FIG. 2E).

Referring to FIG. 2E again, the thin film transistor structure 20 formed by aforementioned method includes a thin film transistor 200 and a pixel area 207, wherein the thin film transistor 200 includes the substrate 201, the gate 202, the gate dielectric layer 204, the source 205, the drain 206 and the transparent material layer 208, and the pixel area 207 includes the pixel electrode layer 206b. The gate 202 is formed on the substrate 201; the gate dielectric layer 204 is formed on the gate 202; the source 205 and the drain 206 are formed on the gate dielectric layer 204; and the transparent material layer 208 has the channel area 208a and the insulating area 208b, wherein the channel area 208a is disposed on the portion of the gate dielectric layer 204 located between the source 205 and the drain 206; and the insulating area 208b is disposed on the channel area 208a, the source 205, and the drain 206.

Referring to FIG. 2 again, because the pixel electrode layer 206b extending from the drain 206 can be formed by one single film-forming process for forming the source 205 and the drain 206, thus the steps and photo-masks traditionally required for defining the contact via holes and the individual pixel electrode can be omitted. Accordingly the manufacturing process can be simplified. In addition, because both of the pixel area 207 and the pixel electrode 206b are composed of transparent materials, thereby the aperture ration of the liquid crystal display (LCD) utilizing the thin film transistor structure 20 can be improved.

According to aforementioned embodiments, a thin film transistor structure and the manufacturing method thereof are provided. A continuous sputtering deposition is performed to form a transparent material layer, wherein the transparent material layer having a channel area and an insulating area overlays on the gate dielectric layer, the source and the drain without venting. During the continuous sputtering deposition, the concentration of oxygen implanted into the channel area and the insulating area can be adjusted by controlling the oxygen (O₂)/argon (Ar) flow rate of the sputtering deposition atmosphere. Therefore, the channel area possessing semiconductor properties and the insulating area possessing insulating properties can be formed in a semiconductor layer by a single process; such that, the procedures for manufacturing the thin film transistor structure can be simplified; the manufacturing cost can be reduced; and the yield of the thin film transistor structure can be improved.

Besides, since the present method can further provides the indium tin oxide (ITO) based source and drain structure, wherein the drain has an extending portion serves as a pixel electrode electrically connected to the pixel layer, thus the additional contact via holes definition process and the process for forming the conventional pixel electrode are not essential any more and even can be omitted, and the photo masks required by the aforementioned process also can be omitted. Accordingly the manufacturing procedures can be simplified; meanwhile the aperture ratio of an LCD which utilizes the present thin film transistor structure can be improved.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A thin film transistor structure, comprising:
a substrate;
a gate, formed on the substrate;
a gate dielectric layer, formed on the gate;
a source and a drain, formed on the gate dielectric layer; and
a transparent material layer, having a channel area and an insulating area, wherein the channel area is disposed on a portion of the gate dielectric layer located between the source and the drain; and the insulating area covers on the channel area, the source and the drain.

2. The thin film transistor structure of claim 1, wherein the transparent material layer includes indium gallium zinc oxide (IGZO), and the portion of the transparent material layer on which the channel area is defined has a molecular proportion of indium (In), gallium (Ga), zinc (Zn) and Oxygen (O) substantially about 1:1:1:(3.5˜4.5).

3. The thin film transistor structure of claim 1, wherein the channel area has a thickness substantially ranging from 50 nm to 100 nm and a resistance substantially ranging from 1×10¹ ohm-cm to 1×10⁶ ohm-cm, and the insulating area has a thickness substantially ranging from 50 nm to 500 nm and a resistance substantially greater than 1×10⁶ ohm-cm.

4. The thin film transistor structure of claim 1, wherein the source and the drain include material selected from the group consisting of indium tin oxide (ITO), indium zinc oxide (IZO), and indium gallium zinc oxide (IGZO).

5. The thin film transistor structure of claim 1, further comprising a pixel electrode layer formed on the gate dielectric layer and electrically connected to the drain.

6. The thin film transistor structure of claim 5, wherein the drain and the pixel electrode layer are formed by a same conductive layer.

7. The thin film transistor structure of claim 1, wherein the substrate is a glass substrate or a plastic substrate, and the gate dielectric layer includes material selected from the group consisting of silicon nitride (SiNₓ), silicon oxide (SiOₓ), silicon oxy-nitride (SiNₓO_{y}), aluminum oxide (AlOₓ), and hafnium oxide (HfOₓ).

8. The thin film transistor structure of claim 1, further comprising a protection layer formed on the insulating area, wherein the protection layer includes material selected from the group consisting of silicon nitride (SiNₓ), silicon oxide (SiOₓ), silicon oxy-nitride (SiNₓO_{y}), aluminum oxide (AlOₓ), and resin.

9. A method for fabricating a thin film transistor, comprising:
providing a substrate having a gate formed thereon;
forming a gate dielectric layer on the gate;
forming a source and a drain on the gate dielectric layer; and
forming a transparent material layer having a channel area and an insulating area, wherein the channel area is disposed on a portion of the gate dielectric layer located between the source and the drain; and the insulating area covers on the channel area, the source and the drain.

10. The method of claim 9, wherein the transparent material layer is formed by a continuous sputtering deposition, whereby the channel area and the insulating area are formed on the source, the drain and the gate dielectric layer without venting.
